(19) United States
(12) Patent Application Publication
(10) Pub. No.: US 2021/0343506 A1
(43) Pub. Date: Nov. 4, 2021

(54) Methods And Apparatus For Pulsed Inductively Coupled Plasma For Surface Treatment Processing

(71) Applicants: Mattson Technology, Inc., Fremont, CA (US); Beijing E-Town Semiconductor Technology Co., Ltd., Beijing (CN)

(72) Inventors: Ting Xie, Fremont, CA (US); Haochen Li, Fremont, CA (US); Shuang Meng, Newark, CA (US); Qiqun Zhang, Palo Alto, CA (US); Dave Kohl, Fremont, CA (US); Shawming Ma, Sunnyvale, CA (US); Haichun Yang, San Jose, CA (US); Hua Chung, Saratoga, CA (US); Ryan M. Pakulski, Brentwood, CA (US); Michael X. Yang, Palo Alto, CA (US)

(21) Appl. No.: 17/245,803

(22) Filed: Apr. 30, 2021

Related U.S. Application Data
(60) Provisional application No. 63/024,540, filed on May 14, 2020.
(60) Provisional application No. 63/018,566, filed on May 1, 2020.

(51) Int. Cl. H01J 37/32; H01L 21/67; H01L 21/3065

(52) U.S. Cl. CPC H01J 37/32422; H01J 37/32715; H01J 37/321; C23C 16/50; H01L 21/67069; H01L 21/3065; H01J 2237/334; H01J 37/3244

(57) ABSTRACT

Apparatus and methods for processing a workpiece using a plasma are provided. In one example implementation, an apparatus can include a processing chamber. The apparatus can include a plasma chamber comprising a dielectric tube defining a sidewall. The apparatus can include an inductively coupled plasma source. The inductively coupled plasma source can include an RF generator configured to energize an induction coil disposed about the dielectric tube. The apparatus can include a separation grid separating the processing chamber from the plasma chamber. The apparatus can include a controller configured to operate the inductively coupled plasma source in a pulsed mode. During the pulsed mode the RF generator is configured to apply a plurality of pulses of RF power to the induction coil. A frequency of pulses can be in a range of about 1 kHz to about 100 kHz.

### PRIORITY CLAIM

The present application claims the benefit of priority of U.S. Provisional Application Ser. No. 63/018,566, titled Methods and Apparatus for Pulsed Inductively Coupled Plasma for Surface Treatment Processing, filed on May 1, 2020, which is incorporated herein by reference. The present application claims the benefit of priority of U.S. Provisional Application Ser. No. 63/024,540, titled Methods and Apparatus for Pulsed Inductively Coupled Plasma for Surface Treatment Processing, filed on May 14, 2020, which is incorporated herein by reference.

### FIELD

The present disclosure relates generally to systems and methods for processing semiconductor workpieces.

### BACKGROUND

Plasma processing systems have been used in integrated circuit manufacturing to process workpieces (e.g., semiconductor wafers) to form integrated circuits and other electronic products. Plasma processing systems can include capacitively coupled plasma sources or inductively coupled plasma sources. During an inductively coupled plasma process, a substantial number of ions and radicals are generated from a processing gas in the plasma. These ions and radicals can react with the workpiece in physical or chemical ways to yield the etching of materials, treatment of a surface, deposition of materials, and other processes.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus. The apparatus includes a processing chamber having a workpiece support. The workpiece support configured to support a workpiece during plasma processing. The apparatus includes a plasma chamber. The plasma chamber includes a dielectric tube defining a sidewall of the plasma chamber. The apparatus includes a gas source operable to introduce a process gas into the plasma chamber. The apparatus includes an inductively coupled plasma source configured to induce a plasma in the process gas in the plasma chamber. The inductively coupled plasma source includes an RF generator configured to energize an induction coil disposed about the dielectric tube with RF power. The apparatus includes a separation grid separating the processing chamber from the plasma chamber. The separation grid is operable to filter ions generated in the plasma. The separation grid is operable to allow neutral radicals to pass through the separation grid for exposure to the workpiece during plasma processing. The apparatus includes a controller configured to operate the inductively coupled plasma source in a pulsed mode. During the pulsed mode, the RF generator is configured to apply a plurality of pulses of RF power to the induction coil. A frequency of pulses in the RF power can be in a range of about 1 kHz to about 100 kHz.

Other example aspects of the present disclosure are directed to systems, methods, and apparatus for processing of workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus according to example embodiments of the present disclosure;

FIG. 2 depicts example pulsed RF power according to example embodiments of the present disclosure;

FIG. 3 depicts example pulsed RF power according to example embodiments of the present disclosure;

FIG. 4 depicts example pulsed RF power according to example embodiments of the present disclosure;

FIG. 5 depicts example post plasma gas injection according to example embodiments of the present disclosure;

FIG. 6 depicts an example plasma processing apparatus according to example embodiments of the present disclosure;

FIG. 7 depicts an example plasma processing apparatus according to example embodiments of the present disclosure;

FIG. 8 depicts a flow diagram of an example method according to example embodiments of the present disclosure; and

FIGS. 9 and 10 depicts example process results according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to apparatus and methods for processing a workpiece (e.g., a semiconductor workpiece) using a plasma. A plasma processing apparatus can include a remote plasma source that is configured to generate a plasma in a plasma chamber that is separated from a processing chamber (e.g., via a separation grid) in which a workpiece is located. An inductively coupled remote plasma source can include a dielectric tube (e.g., a quartz tube or a ceramic tube) forming at least a portion of sidewall of the plasma chamber. An induction coil can be disposed about the dielectric tube. The induction coil can be energized with RF power to generate a plasma from a process gas in the plasma chamber. Species generated in the plasma can include ions and neutral radicals. The separation grid can filter a substantial portion of the ions to prevent ion flow into the processing chamber. Neutral radicals can pass through the separation grid into the processing chamber. The neutral radicals can be exposed to the workpiece for materials removal, surface treatment, and/or deposition.

Species (e.g., ions and radicals) generated in the plasma can react chemically and/or physically with parts of the plasma chamber, including the dielectric tube that forms the inner wall of the plasma chamber. The reaction can lead to damage to parts including a thinning of the dielectric tube wall, introducing haze areas on the tube, and other damage, which can shorten the lifetime of the dielectric tube. One way to reduce damage to parts (e.g., a dielectric tube) caused by a plasma can be to narrow down the process window for various process parameters, such as limiting the RF power, lowering the pressure, etc. This can lead to a compromise between process performance (e.g., selectivity, uniformity, yield) and apparatus performance (parts lifetime, costs, etc.).

According to example aspects of the present disclosure, a remote plasma source is operated in a pulsed mode. In the pulsed mode, RF power is applied in a plurality of pulses to an induction coil to generate a plasma in a plasma chamber. A pulse occurs when RF power is applied to the coil with RF power for a first time period followed by a second time period where RF power is not applied (e.g., applied at zero RF power or reduced RF power). The pulse period is the total time associated with one pulse cycle during which RF power is applied and RF power is not applied (or reduced). A duty cycle refers to the percentage of the pulse period during which RF power is applied relative to when RF power is not applied (or reduced).

According to example aspects of the present disclosure, a frequency of the RF power applied to the induction coil to generate the plasma is in the range of about 400 kHz to about 60 MHz. The frequency of pulses (e.g., frequency of pulse cycles) can be in the range of about 1 kHz to about 100 kHz. In some embodiments, the plurality of pulses of RF power applied to the induction coil can be associated with a duty cycle in a range of about 10% to about 90%, such as about 10% to about 70%, such as about 10% to about 50%.

Example aspects of the present disclosure can provide a number of technical effects and benefits. For instance, operating the remote plasma source in a pulsed mode can at least partially resolve the tradeoff between process performance and apparatus performance. The present inventors have discovered that using a pulsed plasma in conjunction with a remote plasma source (e.g., with filtering of ions by a separation grid) where the frequency of pulses (e.g., frequency of pulse cycles) is in the range of about 1 kHz to about 100 kHz can result in a reduction of the temperature of the dielectric tube defining a sidewall of the plasma chamber. This indicates that less damage to the dielectric tube is caused by the plasma. Since damage to the dielectric tube has been reduced by operating the remote plasma source in the pulsed mode, a broader process window can be used to provide for better process performance. As a result, operating the remote plasma source in a pulsed mode can be beneficial to prolong lifetime of the plasma processing apparatus and the dielectric tube and to provide larger process window(s) for process parameters(s), leading to better apparatus performance and process performance.

In addition, the present inventors have discovered that use of a pulsed RF power in conjunction with a remote plasma source that is separated from a processing chamber (e.g., and a workpiece) by a separation grid configured to perform ion filtering can provide advantages. For instance, use of pulsed RF power can allow for increased number of lower energy neutral radicals to pass through the grid. This can increase desired species concentration in the process chamber for some process applications.

As used here, the use of the term “about” or “approximately” in conjunction with a numerical value refers to within 10% of the numerical value. The use of the term “about” or “approximately” in conjunction with the number zero RF power refers to less than about 250 Watts. As used herein, a “remote plasma” refers to a plasma generated remotely from a workpiece, such as in a plasma chamber separated from a workpiece by a separation grid configured to perform ion filtering. As used herein, a “direct plasma” refers to a plasma that is directly exposed to a workpiece, such as a plasma generated in a processing chamber having a pedestal operable to support the workpiece. A “workpiece” refers to any substrate that is processed by a plasma, including a semiconductor substrate, semiconductor wafer, or other suitable workpiece.

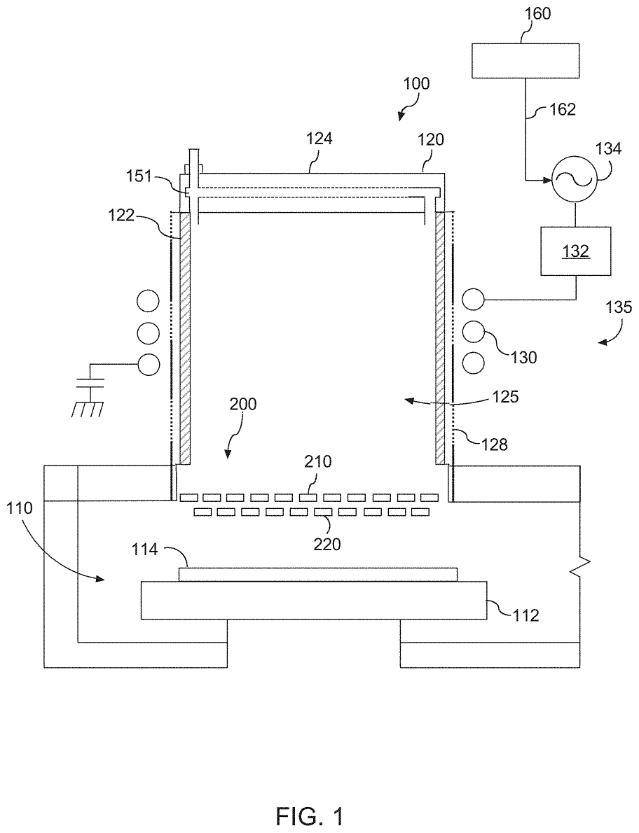

FIG. 1 depicts an example plasma processing apparatus 100 that can be used to perform processes according to example embodiments of the present disclosure. As illustrated, plasma processing apparatus 100 includes a processing chamber 110 and a plasma chamber 120 that is separated from the processing chamber 110. Processing chamber 110 includes a workpiece support or pedestal 112 configured to support a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric tube 122 that forms at least a portion of a sidewall of the plasm chamber 120 and a ceiling 124. The dielectric tube 122, ceiling 124, and separation grid 200 define a plasma chamber interior 125. Dielectric tube 122 can be formed from a dielectric material, such as quartz and/or ceramic (e.g., alumina). The inductively coupled plasma source 135 can include an induction coil 130 disposed adjacent the dielectric tube 122 about the plasma chamber 120. The induction coil 130 is coupled to an RF generator 134 through a suitable matching network 132. Process gases (e.g., as described in detail below) can be provided to the chamber interior from gas supply 150 and annular gas distribution channel 151 or other suitable gas introduction mechanism. When the induction coil 130 is energized with RF power from the RF generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 1, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded. In some embodiments, the grid assembly can include a single grid with a single grid plate. As shown in FIG. 1, the apparatus 100 can include a gas delivery system 150 configured to deliver process gas to the plasma chamber 120, for instance, via gas distribution channel 151 or other distribution system (e.g., showerhead).

According to example aspects of the present disclosure, the plasma processing apparatus 100 can include a controller 160. In some embodiments, the controller 160 can send control signals to various components in the plasma processing apparatus 100 to control process parameters (e.g., RF power, temperature, pressure, gas flow rates, etc.). In some implementations, the controller 160 can include one or more processors and one or more memory devices. The one or more processors can execute computer-readable instructions stored on the one or more processors to cause the one or more processors to perform operations, such as controlling an RF generator to operate in a pulsed mode (e.g., to provide pulsed RF power) as described herein. When the RF generator is in the pulsed mode, the RF generator is configured to apply a plurality of pulses of RF power to the induction coil.

For instance, as shown in FIG. 1, the controller 160 can send a control signal 162 to RF generator 134 to operate the RF generator 134 in a pulsed mode. The controller 160 can control the RF generator to apply a plurality of pulses of RF power to the induction coil 130 to generate a remote plasma in the plasma chamber 120. In some embodiments, the frequency of RF power provided by the RF generator 134 is in a range of about 400 kHz to about 60 MHz.

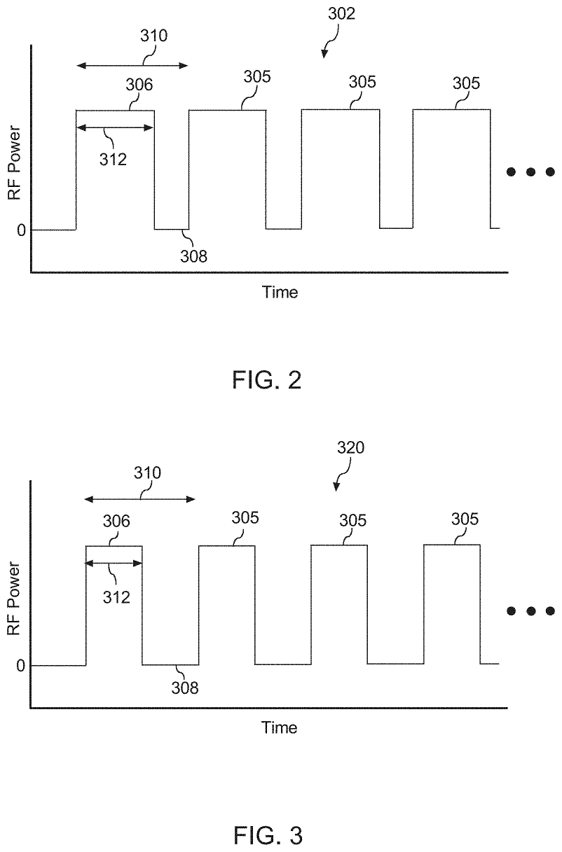

FIG. 2 depicts pulsed RF power 302 having a plurality of pulses 305 according to example embodiments of the present disclosure. The pulsed RF power 302 can be provided by an RF generator to operate an inductive plasma source in a pulsed mode according to example embodiments of the present disclosure. As shown, the RF generator provides a plurality of pulses 305. Each pulse 305 is associated with an “on portion” 306 where RF power is provided to an induction coil and an “off portion” 308 where zero RF power or reduced RF power (relative to the “on portion”) is provided to the induction coil. Each pulse 305 has a pulse period 310 (time period associated with each full cycle). The pulse period 310 can have a duration that begins at the start of an “on portion” 306 and terminates at an end of the “off portion” 308. The start of the “on portion” 306 can be defined as when time when RF power has risen to a level of at least 50% of the peak RF power. The end of the “off portion” 308 can be defined as the time when RF power associated with the next pulse in the sequence has risen to a level of at least 50% of the peak RF power.

The pulsed RF power 302 provided by the RF generator can have a duty cycle. The duty cycle can be defined as a percentage of the duration 312 of the “on portion” relative to the total duration of the pulse period 310. In the example of FIG. 2, the duty cycle is greater than about 75%, such as about 90%. In addition, the pulsed RF power 302 can have a frequency of pulses (e.g., number of pulse cycles per second). In some embodiments, the frequency of pulses can be in the range of about 1 kHz to about 100 kHz.

FIG. 3 depicts pulsed RF power 320 having a plurality of pulses 305 according to example embodiments of the present disclosure. The pulsed RF power 320 is similar to the pulsed RF power 302 of FIG. 2. However, a duty cycle of the pulsed RF power 320 of FIG. 3 is less than a duty cycle of pulsed RF power 302 of FIG. 2. For instance, the duty cycle of pulsed RF power 320 is about 50%.

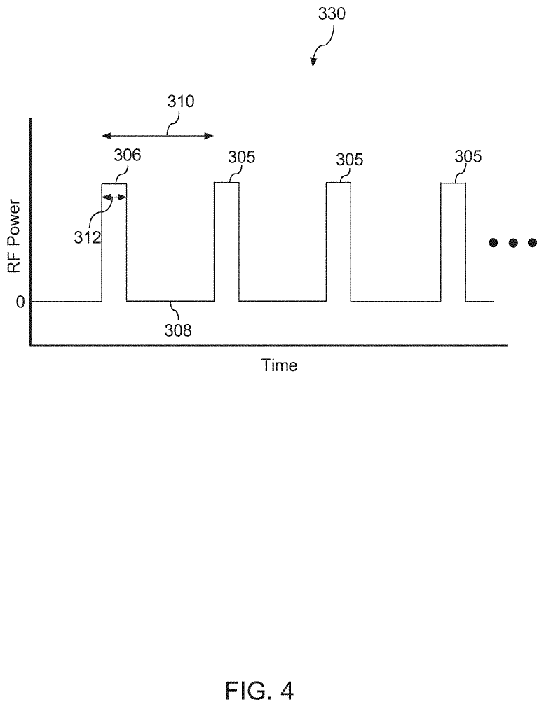

FIG. 4 depicts pulsed RF power 320 having a plurality of pulses 305 according to example embodiments of the present disclosure. The pulsed RF power 320 is similar to the pulsed RF power 302 of FIG. 2. However, a duty cycle of the pulsed RF power 330 of FIG. 4 is less than a duty cycle of pulsed RF power 302 of FIG. 2 and less than a duty cycle of pulsed RF power 3020 of FIG. 3. For instance, the duty cycle of pulsed RF power 330 is about 10%.

Square wave pulses are illustrated in FIGS. 2-4 for purposes of illustration and discussion. Those of ordinary skill in the art, using the disclosures provided herein, will understand that any shape pulse can be used (e.g., with linear, exponential, logarithmic, etc. ramp ups and ramp downs) without deviating from the scope of the present disclosure.

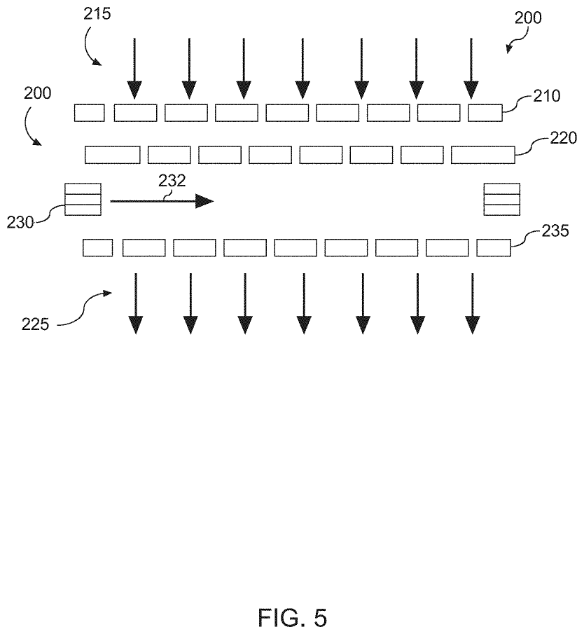

In some embodiments, pulsed RF power can be used in conjunction with a remote plasma source and with post plasma gas injection that injects gas into a process chamber post filtering by a separation grid. FIG. 5 depicts example post plasma gas injection into a plasma processing apparatus according to example embodiments of the present disclosure. As shown, FIG. 5 depicts an example separation grid 200 for injection of a gas according to example embodiments of the present disclosure. The separation grid 200 includes a first grid plate 210 and a second grid plate 220 disposed in parallel relationship. The first grid plate 210 and the second grid plate 220 can provide for ion/UV filtering.

The first grid plate 210 can have a first grid pattern having a plurality of holes. The second grid plate 220 can have a second grid pattern having a plurality of holes. The first grid pattern can be the same as or different from the second grid pattern. Species 215 from the plasma can be exposed to the separation grid 200. Charged particles (e.g., ions) can recombine on the walls in their path through the holes of each grid plate 210, 220 in the separation grid 200. Neutral species can flow relatively freely through the holes in the first grid plate 210 and the second grid plate 220.

Subsequent to the second grid plate 220, a gas injection port 230 can be configured to introduce a gas 232 into the species passing through the separation grid 200. A mixture 225 resulting from the injection of the gas can pass through a third grid plate 235 for exposure to the workpiece in the processing chamber.

The present example is discussed with reference to a separation grid with three grid plates for example purposes. Those of ordinary skill in the art, using the disclosures provided herein, will understand that more or fewer grid plates can be used without deviating from the scope of the present disclosure. In addition, the water vapor can be mixed with the species at any point in the separation grid and/or after the separation grid in the processing chamber. For instance, the water vapor injection source 230 can be located between first grid plate 210 and second grid plate 220.

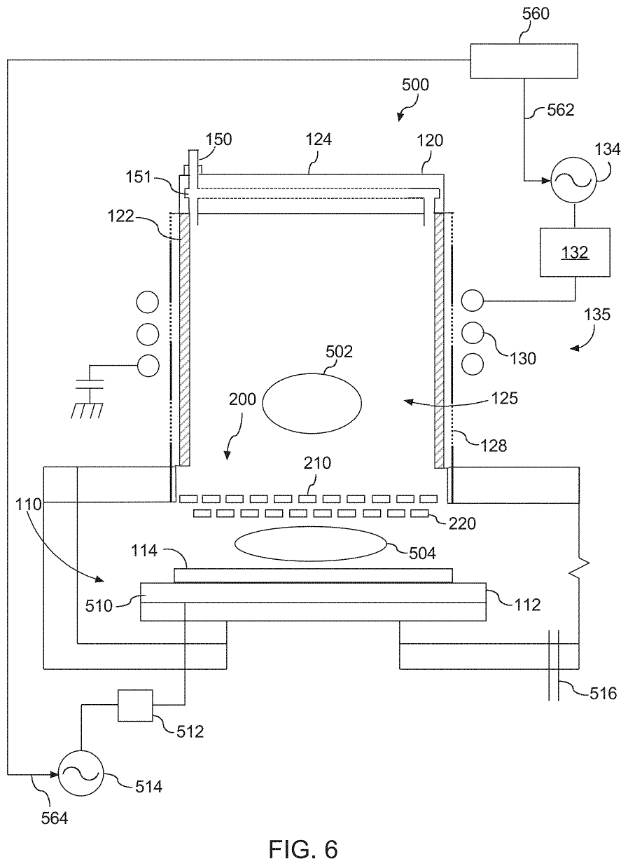

FIG. 6 depicts an example plasma processing apparatus 500 that can be used to implement processes according to example embodiments of the present disclosure. The plasma processing apparatus 500 is similar to the plasma processing apparatus 100 of FIG. 1.

More particularly, plasma processing apparatus 500 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric tube 122 and a ceiling 124. The dielectric tube 122, ceiling 124, and separation grid 200 define a plasma chamber interior 125. Dielectric tube 122 can be formed from a dielectric material, such as quartz and/or ceramic (e.g., alumina). The inductively coupled plasma source 135 can include an induction coil 130 disposed adjacent to the dielectric tube 122 about the plasma chamber 120. The induction coil 130 is coupled to an RF generator 134 through a suitable matching network 132. Process gases (e.g., an inert gas) can be provided to the chamber interior from gas supply 150 and annular gas distribution channel 151 or other suitable gas introduction mechanism. When the induction coil 130 is energized with RF power from the RF generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 76, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 500 of FIG. 6 is operable to generate a first plasma 502 (e.g., a remote plasma) in the plasma chamber 120 and a second plasma 504 (e.g., a direct plasma) in the processing chamber 110. More particularly, the plasma processing apparatus 500 of FIG. 6 includes a bias source having bias electrode 510 in the pedestal 112. The bias electrode 510 can be coupled to an RF generator 514 via a suitable matching network 512. When the bias electrode 510 is energized with RF power, a second plasma 504 can be generated from a mixture in the processing chamber 110 for direct exposure to the workpiece 114. The processing chamber 110 can include a gas exhaust port 516 for evacuating a gas from the processing chamber 110. As shown in FIG. 6, the apparatus 100 can include a gas delivery system 150 configured to deliver process gas to the plasma chamber 120, for instance, via gas distribution channel 151 or other distribution system (e.g., showerhead).

According to example aspects of the present disclosure, the plasma processing apparatus 500 can include a controller 560. In some embodiments, the controller 560 can send control signals to various components in the plasma processing apparatus 500 to control process parameters (e.g., RF power, temperature, pressure, gas flow rates, etc.). In some implementations, the controller 560 can include one or more processors and one or more memory devices. The one or more processors can execute computer-readable instructions stored on the one or more processors to cause the one or more processors to perform operations, such as controlling an RF generator to operate in a pulsed mode (e.g., to provide pulsed RF power) as described herein.

For instance, as shown in FIG. 6, the controller 560 can send a control signal 562 to RF generator 134 to operate the RF generator 134 in a pulsed mode. In the pulsed mode, the RF generator 134 provides a plurality of pulses of RF power to the induction coil 130 to generate a remote plasma in the plasma chamber 120.

As discussed above, in some embodiments, the frequency of RF power provided by the RF generator 134 is in a range of about 400 kHz to about 60 MHz. The frequency of pulses (e.g., frequency of pulse cycles) can be in the range of about 1 kHz to about 100 kHz. In some embodiments, the plurality of pulses of RF power applied to the induction coil can be associated with a duty cycle in a range of about 10% to about 90%, such as about 10% to about 70%, such as about 10% to about 50%.

In addition and/or in the alternative, the controller 560 can send a control signal 564 to RF generator 514 to operate the RF generator 514 in a pulsed mode. In the pulsed mode, the RF generator 514 provides a plurality of pulses of RF power to the bias electrode 510 to generate a direct plasma in the processing chamber 110.

As discussed above, in some embodiments, the frequency of RF power provided by the RF generator 514 is in a range of about 400 kHz to about 60 MHz. The frequency of pulses (e.g., frequency of pulse cycles) can be in the range of about 1 kHz to about 100 kHz. In some embodiments, the plurality of pulses of RF power applied to the bias electrode 510 can be associated with a duty cycle in a range of about 10% to about 90%, such as about 10% to about 70%, such as about 10% to about 50%.

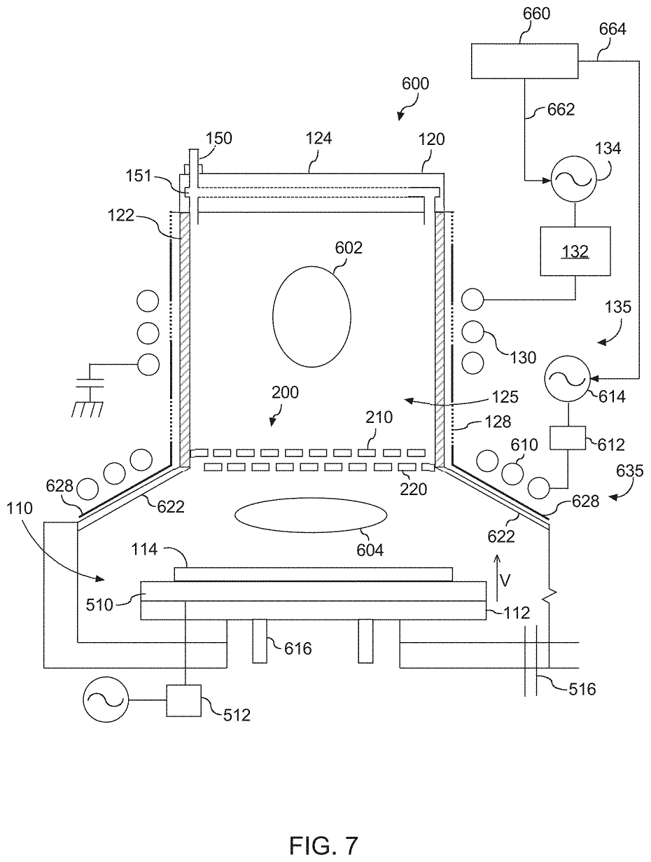

FIG. 7 depicts a processing chamber 600 similar to that of FIG. 1 and FIG. 6. More particularly, plasma processing apparatus 600 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric tube 122 and a ceiling 124. The dielectric tube 122, ceiling 124, and separation grid 200 define a plasma chamber interior 125. Dielectric tube 122 can be formed from a dielectric material, such as quartz and/or ceramic (e.g., alumina). The inductively coupled plasma source 135 can include an induction coil 130 disposed adjacent to the dielectric tube 122 about the plasma chamber 120. The induction coil 130 is coupled to an RF generator 134 through a suitable matching network 132. Process gas (e.g., an inert gas) can be provided to the chamber interior from gas supply 150 and annular gas distribution channel 151 or other suitable gas introduction mechanism. When the induction coil 130 is energized with RF power from the RF generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 7, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 600 of FIG. 7 is operable to generate a first plasma 602 (e.g., a remote plasma) in the plasma chamber 120 and a second plasma 604 (e.g., a direct plasma) in the processing chamber 110. As shown, the plasma processing apparatus 600 can include an angled dielectric sidewall 622 that extends from the dielectric tube 122 associated with the remote plasma chamber 120. The angled dielectric sidewall 622 can form a part of the processing chamber 110.

A second inductive plasma source 635 can be located proximate to the dielectric sidewall 622. The second inductive plasma source 635 can include an induction coil 610 coupled to an RF generator 614 via a suitable matching network 612. The induction coil 610, when energized with RF power, can induce a direct plasma 604 from a mixture in the processing chamber 110. A Faraday shield 628 can be disposed between the induction coil 610 and the sidewall 622.

The pedestal 112 can be movable in a vertical direction V. For instance, the pedestal 112 can include a vertical lift 616 that can be configured to adjust a distance between the pedestal 112 and the separation grid assembly 200. As one example, the pedestal 112 can be located in a first vertical position for processing using the remote plasma 602. The pedestal 112 can be in a second vertical position for processing using the direct plasma 604. The first vertical position can be closer to the separation grid assembly 200 relative to the second vertical position.

The plasma processing apparatus 600 of FIG. 7 includes a bias source having bias electrode 510 in the pedestal 112. The bias electrode 510 can be coupled to an RF generator 514 via a suitable matching network 512. The processing chamber 110 can include a gas exhaust port 516 for evacuating a gas from the processing chamber 110. As shown in FIG. 7, the apparatus 100 can include a gas delivery system 150 configured to deliver process gas to the plasma chamber 120, for instance, via gas distribution channel 151 or other distribution system (e.g., showerhead).

According to example aspects of the present disclosure, the plasma processing apparatus 600 can include a controller 660. In some embodiments, the controller 660 can send control signals to various components in the plasma processing apparatus 600 to control process parameters (e.g., RF power, temperature, pressure, gas flow rates, etc.). In some implementations, the controller 660 can include one or more processors and one or more memory devices. The one or more processors can execute computer-readable instructions stored on the one or more processors to cause the one or more processors to perform operations, such as controlling an RF generator to operate in a pulsed mode (e.g., to provide pulsed RF power) as described herein.

For instance, as shown in FIG. 7, the controller 660 can send a control signal 662 to RF generator 134 to operate the RF generator 134 in a pulsed mode. In the pulsed mode, the RF generator 134 provides a plurality of pulses of RF power to the induction coil 130 to generate a remote plasma in the plasma chamber 120.

As discussed above, in some embodiments, the frequency of RF power provided by the RF generator 134 is in a range of about 400 kHz to about 60 MHz. The frequency of pulses (e.g., frequency of pulse cycles) can be in the range of about 1 kHz to about 100 kHz. In some embodiments, the plurality of pulses of RF power applied to the induction coil can be associated with a duty cycle in a range of about 10% to about 90%, such as about 10% to about 70%, such as about 10% to about 50%.

In addition and/or in the alternative, the controller 660 can send a control signal 664 to RF generator 614 to operate the RF generator 614 in a pulsed mode. In the pulsed mode, the RF generator 614 provides a plurality of pulses of RF power to the induction coil 610 to generate a direct plasma in the processing chamber 110.

As discussed above, in some embodiments, the frequency of RF power provided by the RF generator 614 is in a range of about 400 kHz to about 60 MHz. The frequency of pulses (e.g., frequency of pulse cycles) can be in the range of about 1 kHz to about 100 kHz. In some embodiments, the plurality of pulses of RF power applied to the induction coil 630 can be associated with a duty cycle in a range of about 10% to about 90%, such as about 10% to about 70%, such as about 10% to about 50%.

In addition and/or in the alternative, the controller 660 can send a control signal 668 to RF generator 514 to operate the RF generator 514 in a pulsed mode. In the pulsed mode, the RF generator 514 provides a plurality of pulses of RF power to the bias electrode 510 to generate a direct plasma in the processing chamber 110.

As discussed above, in some embodiments, the frequency of RF power provided by the RF generator 514 is in a range of about 400 kHz to about 60 MHz. The frequency of pulses (e.g., frequency of pulse cycles) can be in the range of about 1 kHz to about 100 kHz. In some embodiments, the plurality of pulses of RF power applied to the bias electrode 614 can be associated with a duty cycle in a range of about 10% to about 90%, such as about 10% to about 70%, such as about 10% to about 50%.

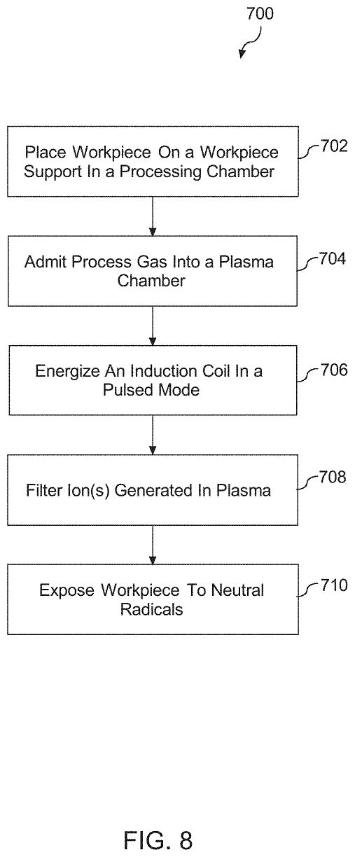

FIG. 8 depicts a flow diagram of one example method (700) according to example aspects of the present disclosure. The method (700) will be discussed with reference to the plasma processing apparatus 100 of FIG. 1 by way of example. The method (700) can be implemented in any suitable plasma processing apparatus. FIG. 7 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (702), the method can include placing a workpiece in a processing chamber of a plasma processing apparatus. The processing chamber can be separated from a plasma chamber (e.g., separated by a separation grid assembly operable for ion filtering). For instance, the method can include placing a workpiece 114 onto workpiece support 112 in the processing chamber 110 of FIG. 1.

At (704), the method can include admitting a process gas mixture into a plasma chamber. For instance, a process gas can be admitted into the plasma chamber interior 125 from the gas source 150 via the annular gas distribution channel 151 or other suitable gas introduction mechanism. Aspects of the present disclosure can be used with any suitable process gas or process gas mixture. The process gas can include a mixture of reactant gases and carrier gases.

At (706), the method can include energizing an inductively coupled plasma source to generate a plasma in the plasma chamber. The plasma can have one or more species. For instance, the induction coil 130 can be energized with RF power from the RF generator 134 to generate a plasma in the plasma chamber interior 125. According to example aspects of the present disclosure, the method can include energizing the induction coil in a pulsed mode with RF power having a plurality of pulses to induce a plasma from the process gas in the plasma chamber.

In the pulsed mode, RF power is applied in a plurality of pulses to an induction coil to generate a plasma in a plasma chamber. According to example aspects of the present disclosure, a frequency of the RF power applied to the induction coil to generate the plasma is in the range of about 400 kHz to about 60 MHz. The frequency of pulses (e.g., frequency of pulse cycles) can be in the range of about 1 kHz to about 100 kHz. In some embodiments, the plurality of pulses of RF power applied to the induction coil can be associated with a duty cycle in a range of about 10% to about 90%, such as about 10% to about 70%, such as about 10% to about 50%.

At (708), the method can include filtering ion(s) from the species. In some embodiments, the one or more ions can be filtered using a separation grid assembly separating the plasma chamber from a processing chamber where the workpiece is located. For instance, the separation grid 200 can be operable to filter ions generated by the plasma. The separation grid 200 can have a plurality of holes. Charged particles (e.g., ions) can recombine on the walls in their path through the plurality of holes. Neutrals (e.g., radicals) can pass through the holes.

In some embodiments, the separation grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

At (710), the method can include exposing the workpiece to neutral radicals. The neutral radicals can chemically and/or physically react with the workpiece surface to provide for an etch process, surface treatment process, and/or deposition process on the workpiece.

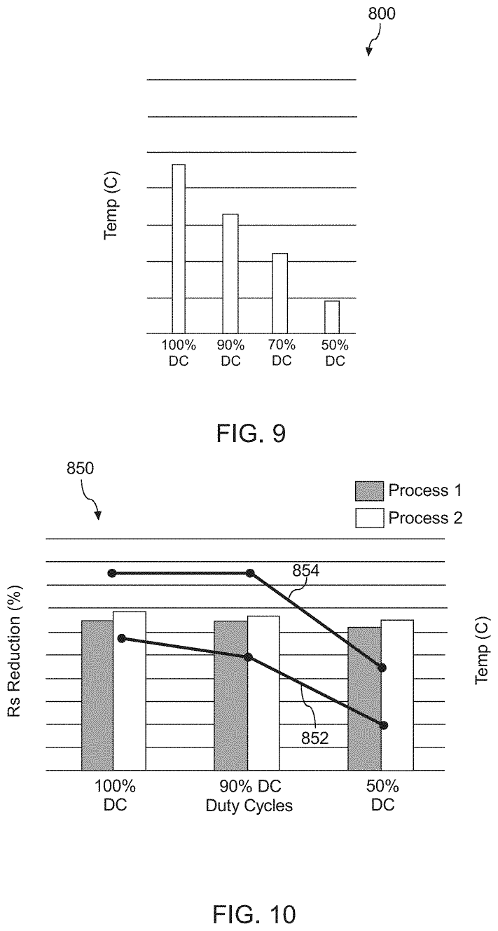

FIG. 9 depicts a graphical representation 800 of a temperature of a dielectric tube (e.g., dielectric tube 122) during performance of a process with a plasma processing apparatus according to example aspects of the present disclosure. FIG. 9 depicts temperature of the dielectric tube on the vertical axis and duty cycle of the pulsed RF power on the horizontal axis. As shown, reducing the duty cycle of the pulsed RF power can result in a reduction of dielectric tube temperature, prolonging life of the dielectric tube.

FIG. 10 depicts a graphical representation 850 of process results and temperature reduction of a dielectric tube for two different processes—Process 1 and Process 2. Process 1 and Process 2 were carried out in a plasma processing apparatus constructed according to the plasma processing apparatus 100 of FIG. 1. Process parameters for Process 1 and Process 2 are provided below. As shown, process performance measured in terms of Rs reduction (for copper) on a workpiece) were maintained relatively the same for duty cycles of 100%, 90%, and 50% of pulsed RF power. However, the temperature of the dielectric tube was reduced at lower duty cycles.

Example process parameters for Process 1 and Process 2 are provided below:

### Process 1

### Process Gas: H2

Dilution Gas: No dilution gas

### Process Pressure: 10 mT to 100 mT

### Inductively Coupled Plasma Source Power: 3000 W-4500 W

### Workpiece Temperature: 250 C-400 C

Process Period: 30 s-300 s
Gas Flow Rates for Process Gas: 100 sccm-1000 sccm

### Process 2

### Process Gas: H2

Dilution Gas: No dilution gas

### Process Pressure: 100 mT to 1000 mT

### Inductively Coupled Plasma Source Power: 3000 W-4500 W

### Workpiece Temperature: 250 C-400 C

Process Period: 30 s-300 s
Gas Flow Rates for Process Gas: 1000 sccm-10000 sccm

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a processing chamber having a workpiece support, the workpiece support configured to support a workpiece during plasma processing;
a plasma chamber, the plasma chamber comprising a dielectric tube defining a sidewall of the plasma chamber;
a gas source operable to introduce a process gas into the plasma chamber;
an inductively coupled plasma source configured to induce a plasma in the process gas in the plasma chamber, the inductively coupled plasma source comprising an RF generator configured to energize an induction coil disposed about the dielectric tube with RF power;
a separation grid separating the processing chamber from the plasma chamber, the separation grid operable to filter ions generated in the plasma, the separation grid operable to allow neutral radicals to pass through the separation grid for exposure to the workpiece during plasma processing;
a controller configured to operate the inductively coupled plasma source in a pulsed mode, wherein during the pulsed mode, the RF generator is configured to apply a plurality of pulses of RF power to the induction coil;
wherein a frequency of pulses in the RF power is in a range of about 1 kHz to about 100 kHz.

2. The plasma processing apparatus of claim 1, wherein the dielectric tube comprises a quartz tube.

3. The plasma processing apparatus of claim 1, wherein the dielectric tube comprises a ceramic tube.

4. The plasma processing apparatus of claim 1, wherein the separation grid is a multi-plate separation grid.

5. The plasma processing apparatus of claim 1, wherein further comprises a gas injection port configured to inject a gas at the separation grid.

6. The plasma processing apparatus of claim 5, wherein the gas injection port is configured to inject a gas between a first grid plate and a second grid plate of the separation grid.

7. The plasma processing apparatus of claim 1, wherein during the pulsed mode, the controller is configured to control the RF generator to apply the plurality of pulses of RF power to the induction coil at a duty cycle in a range of about 10% to about 90%.

8. The plasma processing apparatus of claim 1, wherein during the pulsed mode, the controller is configured to control the RF generator to apply the plurality of pulses of RF power to the induction coil at a duty cycle in a range of about 10% to about 70%.

9. The plasma processing apparatus of claim 1, wherein during the pulsed mode, the controller is configured to control the RF generator to apply the plurality of pulses of RF power to the induction coil at a duty cycle in a range of about 10% to about 50%.

10. The plasma processing apparatus of claim 1, a frequency of the RF power is in a range of about 400 kHz to about 60 MHz.

11. The plasma processing apparatus of claim 1, further comprising a Faraday shield coupled between the induction coil and the dielectric tube, wherein the Faraday shield is grounded.

12. The plasma processing apparatus of claim 1, further comprising a bias electrode disposed in the workpiece support, the bias electrode configured to generate a direct plasma in the processing chamber when energized with RF power.

13. The plasma processing apparatus of claim 1, wherein the processing chamber comprises an angled dielectric sidewall forming a portion of a ceiling of the processing chamber, wherein the plasma processing apparatus further comprises a second induction coil disposed proximate the angled dielectric sidewall, the second induction coil configured to generate a direct plasma in the processing chamber when energized with RF power.

14. A method of processing a workpiece in a plasma processing apparatus, the method comprising:
placing the workpiece on a workpiece support in a processing chamber;
admitting a process gas into a plasma chamber, the plasma chamber comprising a dielectric tube defining a sidewall of the plasma chamber;
energizing an induction coil disposed about the dielectric tube in a pulsed mode with RF power having a plurality of pulses to induce a plasma from the process gas in the plasma chamber, the plasma comprising one or more species;
filtering ions in the one or more species using a separation grid separating the plasma chamber from the processing chamber;
exposing the workpiece to neutral radicals generated in the plasma when energizing the induction coil in the pulsed mode;
wherein a frequency of pulses in the RF power is in a range of about 1 kHz to about 100 kHz.

15. The method of claim 14, wherein the dielectric tube comprises a quartz tube.

16. The method of claim 14, wherein the dielectric tube comprises a ceramic tube.

17. The method of claim 14, wherein energizing an induction coil comprising energizing the induction coil with RF power having a plurality of pulses at a duty cycle in a range of about 10% to about 90%.

18. The method of claim 14, wherein a frequency of the RF power is in a range of about 400 kHz to about 60 MHz.
